(19) United States
(12) Patent Application Publication
(10) Pub. No.: US 2025/0221141 A1
(43) Pub. Date: Jul. 3, 2025

(54) TRANSPARENT ELECTRODE HAVING OPTICAL FILTERING FUNCTION, IMAGE SENSOR USING THE TRANSPARENT ELECTRODE, AND METHOD OF FORMING THE TRANSPARENT ELECTRODE

(71) Applicant: VisEra Technologies Company Ltd., Hsin-Chu City (TW)

(72) Inventors: Wen-Yu SHIH, Hsin-Chu City (TW); Lai-Hung LAI, Hsin-Chu City (TW); San-Yuan CHUNG, Hsin-Chu City (TW); Yu-Hsuan PENG, Hsin-Chu City (TW); Di-Rong LU, Hsin-Chu City (TW)

(21) Appl. No.: 18/398,761

(22) Filed: Dec. 28, 2023

(51) Int. Cl. H10K 39/32; H10K 30/82; H10K 71/60

(52) U.S. Cl. CPC H10K 39/32; H10K 30/82; H10K 71/60

(57) ABSTRACT

A transparent electrode having optical filtering function includes a substrate and a conductive stack disposed on the substrate. The conductive stack includes a plurality of metal layers and a plurality of transparent conductive oxide (TCO) layers alternately arranged. A sheet resistance of the conductive stack is less than 35 ohms per square, and an average transmittance at a spectral range from 400 nm to 700 nm of the conductive stack is greater than 50%. An image sensor using the transparent electrode and a method of forming the transparent electrode are also disclosed.

### BACKGROUND

### Field of Invention

The present disclosure relates to a transparent electrode having optical filtering function, an image sensor using the transparent electrode, and a method of forming the transparent electrode.

### Description of Related Art

An image sensor is a kind of semiconductor device that transforms optical images into electrical signals. Image sensors can be generally classified into charge coupled devices (CCDs) and complementary metal oxide semiconductor (CMOS) image sensors. Among these image sensors, a CMOS image sensor includes a photodiode for detecting incident light and transforming it into electrical signals, and logic circuits for transmitting and processing the electrical signals.

In an RGB camera module with a silicon-based image sensor such as CCD or CMOS, an IR-cut filter for cutting near infrared (IR) light is coated on a glass and assembled in a lens module. The lens module is then mounted on the image sensor. Conventional IR-cut filter includes a large number of stacked dielectric layers and is relatively thick. Consequently, IR-cut filter made of all-dielectric filters is expensive and is difficult to manufacture.

### SUMMARY

An aspect of the present disclosure provides a transparent electrode having optical filtering function. The transparent electrode includes a substrate and a conductive stack disposed on the substrate. The conductive stack includes a plurality of metal layers and a plurality of transparent conductive oxide (TCO) layers alternately arranged. A sheet resistance of the conductive stack is less than 35 ohms per square, and an average transmittance at a spectral range from 400 nm to 700 nm of the conductive stack is greater than 50%.

In some embodiments, a thickness of the conductive stack is less than 1.5 μm, and a number of pairs of the metal layers and the TCO layers of the conductive stack is from 10 to 30.

In some embodiments, the conductive stack has a rectangle cross-section.

In some embodiments, the conductive stack has a trapezoid cross-section, and an angle between a sidewall of the conductive stack and a top surface of the substrate is less than 40 degrees.

In some embodiments, an average optical density at a spectral range from 900 nm to 1100 nm of the conductive stack is greater than 2.

In some embodiments, a material of the metal layers is selected from a group consisting of Ag, Au, Cu, Fe, Al, Pt, Ni, and combinations thereof.

In some embodiments, a material of the TCO layers is selected from a group consisting of In₂O₃, In₂O₃—ZnO, AZO, GZO, ITO, IZO, IWO, MZO, ATO, FTO, IGTO, SnO₂, TNO, TIN, Cu₂O, Ta₂Oₓ, GaInOₓ, InGaZnO, ZnₓSnOy, ZnGaₓO_{y}, GaInOₓ, ZnₓIn_{y}O_{z}, VOₓ, and MoOₓ.

In some embodiments, a refractive index of the TCO layers is greater than 1.6, and an extinction coefficient of the TCO layers is less than 0.1, at a spectral range from 400 nm to 700 nm.

In some embodiments, the transparent electrode further includes a cap dielectric covering a top surface and sidewalls of the conductive stack, wherein a thickness of the cap dielectric is greater than 200 nm.

In some embodiments, the transparent electrode further includes a first dielectric layer on the conductive stack, an additional conductive stack on the first dielectric layer, a second dielectric layer on the additional conductive stack, and a metallic via penetrating the conductive stack, the first dielectric layer, the additional conductive stack, and the second dielectric layer.

In some embodiments, S/N ratio of the transparent electrode is greater than 600, at a spectral range from 400 nm to 1000 nm.

In some embodiments, a response time of the transparent electrode is greater than 10⁴ Hz, at an applied voltage of 4V.

In some embodiments, an ON/OFF ratio of the transparent electrode is greater than 10⁴, at an applied voltage of 0.1V.

Another aspect of the present disclosure provides an image sensor. The image sensor includes a semiconductor substrate, a read-out circuit in the semiconductor substrate, a bottom electrode disposed on a surface of the semiconductor substrate, a photoactive layer disposed on the bottom electrode, a transparent electrode disposed on the photoactive layer, and a contact connecting the transparent electrode to the bottom electrode. The transparent electrode includes a substrate and a conductive stack disposed on the substrate. The conductive stack includes a plurality of metal layers and a plurality of transparent conductive oxide (TCO) layers alternately arranged. A sheet resistance of the conductive stack is less than 35 ohms per square, and an average transmittance at a spectral range from 400 nm to 700 nm of the conductive stack is greater than 50%.

In some embodiments, the photoactive layer includes an organic layer, a quantum dot layer, or a perovskite layer.

In some embodiments, the image sensor further includes a micro lens layer on the transparent electrode, a color filter layer disposed between the micro lens layer and the transparent electrode, and a spacing layer disposed between the color filter layer and the transparent electrode.

Another aspect of the present disclosure provides a method of forming a transparent electrode having optical filtering function. The method includes (a) sputtering depositing a metal layer on a substrate; (b) sputtering depositing a transparent conductive oxide (TCO) layer on the substrate; repeating step (a) and step (b) such that a conductive multilayer is formed on the substrate; and patterning the conductive multilayer such that a conductive stack is formed on the substrate, wherein a sheet resistance of the conductive stack is less than 35 ohms per square, and an average transmittance at a spectral range from 400 nm to 700 nm of the conductive stack is greater than 50%.

In some embodiments, the step (a) is performed in Ar atmosphere, and the step (b) is performed in Ar/O₂ atmosphere.

In some embodiments, a process power or a working pressure used in the step (a) is higher than a process power or a working pressure used in the step (b).

In some embodiments, the method further includes prior to the step (a) and the step (b), performing a plasma cleaning process to the substrate.

The transparent electrode provided in the present disclosure not only provides IR cut function, but also achieves the requirements for high transparency and good conductivity simultaneously.

It is to be understood that both the foregoing general description and the following detailed description are by examples, and are intended to provide further explanation of the disclosure as claimed.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure. In the drawings,

FIG. 1 is a schematic cross-sectional view of a transparent electrode having optical filtering function, according to some embodiments of the disclosure;

FIG. 2 is a wavelength to transmittance chart of the conductive stack of the transparent electrode, according to some embodiments of the disclosure;

FIG. 3 is a wavelength to transmittance chart of the conductive stack of the transparent electrode, according to some other embodiments of the disclosure;

FIG. 4 is a wavelength to optical density chart of the conductive stack of the transparent electrode, according to some embodiments of the disclosure;

FIG. 5 is a schematic cross-sectional view of the transparent electrode having optical filtering function, according to some embodiments of the disclosure;

FIG. 6 is a schematic cross-sectional view of the transparent electrode having optical filtering function, according to some embodiments of the disclosure;

FIG. 7 is a schematic cross-sectional view of the transparent electrode having optical filtering function, according to some embodiments of the disclosure;

FIG. 8 is a schematic cross-sectional view of an image sensor, according to some embodiments of the disclosure;

FIG. 9 is a schematic cross-sectional view of an image sensor, according to some other embodiments of the disclosure; and

FIG. 10 is a flow chart of forming a transparent electrode having optical filtering function, according to some embodiments of the disclosure.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

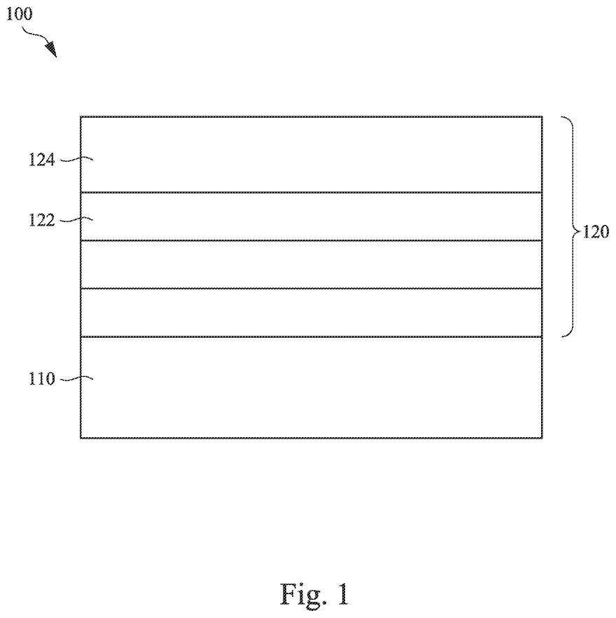

Reference is made to FIG. 1, which is a schematic cross-sectional view of a transparent electrode having optical filtering function, according to some embodiments of the disclosure. The transparent electrode having optical filtering function 100 (hereafter as transparent electrode 100) includes a substrate 110 and a conductive stack 120 disposed on the substrate 110. The substrate 110 is a transparent film. The conductive stack 120 includes two different conductive materials. For example, the conductive stack 120 includes a plurality of metal layers 122 and a plurality of transparent conductive oxide (TCO) layers 124 alternately arranged. The sheet resistance of the conductive stack 120 is less than 35 ohms per square so that the transparent electrode 100 can serve as an electrode. The average transmittance at a spectral range from 400 nm to 700 nm of the conductive stack 120 is greater than 50% so that the transparent electrode 100 can serve as an optical filter.

Unlike the conventional IR-cut filter including a large number of stacked dielectric layers which has a relatively thick thickness such as 4.4 μm for 38 pairs of dielectric layers. The thickness and the pair number of the transparent electrode 100 of the present disclosure are greatly reduced. For example, the thickness of the conductive stack 120 is less than 1.5 μm, and the number of pairs of the metal layers 122 and the TCO layers 124 of the conductive stack 120 is from 10 to 30. In some embodiments, the conductive stack 120 has a rectangular cross-section on the substrate 110.

In some embodiments, the material of the metal layers 122 of the conductive stack 120 is selected from a group consisting of Ag, Au, Cu, Fe, Al, Pt, Ni, and combinations thereof. In some embodiments, the material of the TCO layers 124 of the conductive stack 120 is selected from a group consisting of In₂O₃, In₂O₃—ZnO, AZO, GZO, ITO, IZO, IWO, MZO, ATO, FTO, IGTO, SnO₂, TNO, TIN, Cu₂O, Ta₂Oₓ, GaInOₓ, InGaZnO, ZnₓSnOy, ZnGaₓO_{y}, GaInOₓ, ZnₓIn_{y}O_{z}, VOₓ, and MoOₓ. In some embodiments, the refractive index of the TCO layers 124 is greater than 1.6, and an extinction coefficient of the TCO layers 124 is less than 0.1, at a spectral range from 400 nm to 700 nm.

In some embodiments, the transparent electrode 100 including the conductive stack 120 has low sheet resistance such as less than 35 ohms per square, and the transparent electrode 100 has great operation characteristics. For example, in some embodiments, the signal to noise ratio (S/N ratio) of the transparent electrode 100 is greater than 600, at a spectral range from 400 nm to 1000 nm. For example, in some embodiments, the response time of the transparent electrode 100 is greater than 10⁴ Hz, at an applied voltage of 4V. For example, in some embodiments, the ON/OFF ratio of the transparent electrode 100 is greater than 10⁴, at an applied voltage of 0.1V.

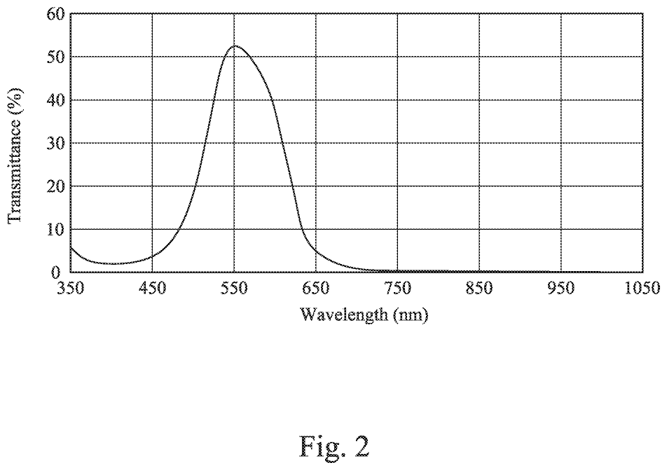

Reference is made to FIG. 2, which is a wavelength to transmittance chart of the conductive stack of the transparent electrode, according to some embodiments of the disclosure. According to some embodiments, the average transmittance of the visible light, e.g. at a spectral range from 400 nm to 700 nm, of the conductive stack 120 is greater than 50%, and the transmittance at the spectral range greater than 750 nm is substantially zero.

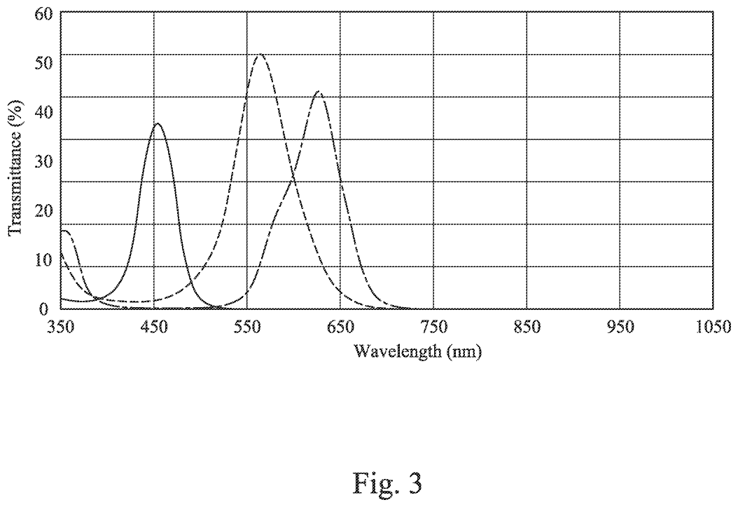

Reference is made to FIG. 3, which is a wavelength to transmittance chart of the conductive stack of the transparent electrode, according to some other embodiments of the disclosure. According to some embodiments, the average transmittance of RGB color lights of the conductive stack 120 is greater than 50%, and the transmittance at the spectral range greater than 750 nm is substantially zero.

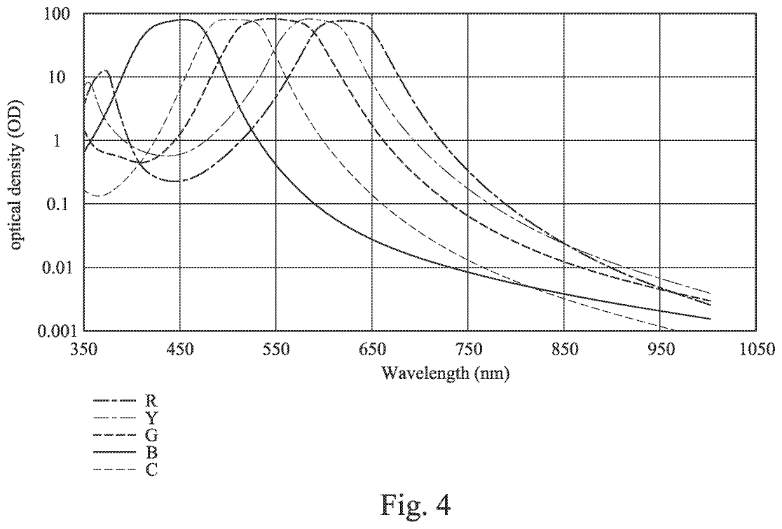

Reference is made to FIG. 4, which is a wavelength to optical density chart of the conductive stack of the transparent electrode, according to some embodiments of the disclosure. According to some embodiments, the average optical density (OD) at a spectral range from 900 nm to 1100 nm of the conductive stack 120 is greater than 2.

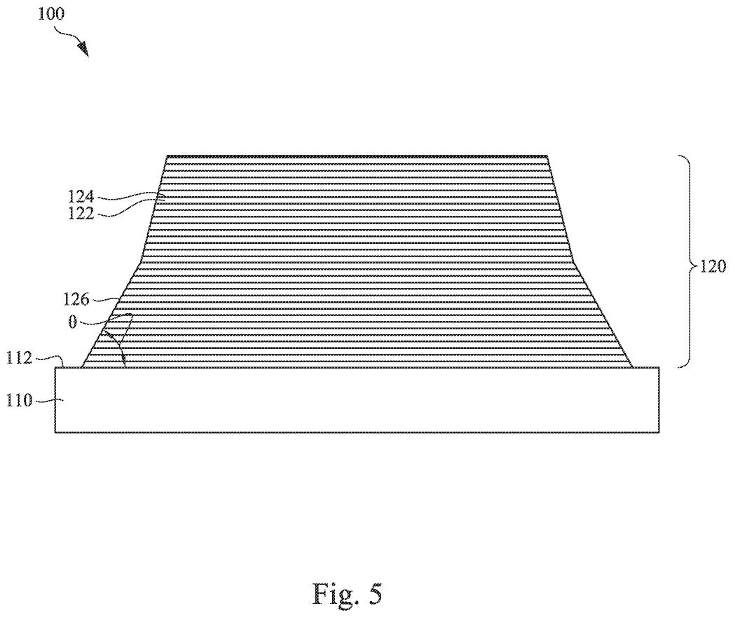

Reference is made to FIG. 5, which is a schematic cross-sectional view of the transparent electrode having optical filtering function, according to some embodiments of the disclosure. In some embodiments, the conductive stack 120 on the substrate 110 is patterned such that the conductive stack has a trapezoid cross-section. In some embodiments, the conductive stack 120 on the substrate 110 is patterned by performing an etching process, and an angle A between a sidewall 126 of the conductive stack 120 and a top surface 112 of the substrate 110 is less than 40 degrees.

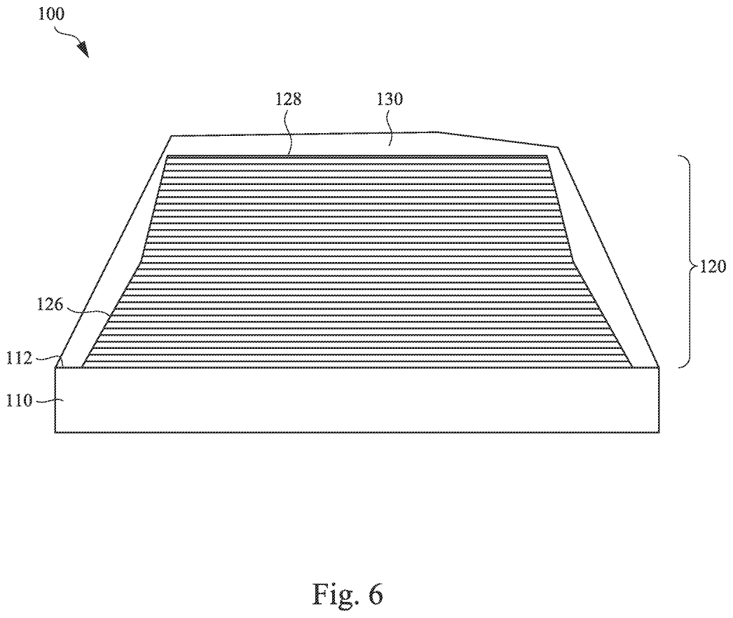

Reference is made to FIG. 6, which is a schematic cross-sectional view of the transparent electrode having optical filtering function, according to some embodiments of the disclosure. In some embodiments, the transparent electrode 100 further includes a capping dielectric 130. The capping dielectric 130 covers the sidewall 126 and the top surface 128 of the conductive stack 120. In some embodiments, the capping dielectric 130 also covers a portion of the top surface 112 of the substrate 110 that surrounding the conductive stack 120. Therefore, the conductive stack 120 is sealed between the capping dielectric 130 and the substrate 110.

In some embodiments, the material of the capping dielectric 130 is an oxide material such as a silicon oxide, and the thickness of the capping dielectric 130 is greater than 200 nm. The capping dielectric 130 can prevent the conductive stack 120 from being damaged by the oxygen and moisture.

In some embodiments, the capping dielectric 130 is substantially conformally deposited on the conductive stack 120 and on the substrate 110. For example, the capping dielectric 130 may have a trapezoid profile when the capping dielectric 130 is deposited on the trapezoid conductive stack 120, as shown in FIG. 6. In some other embodiments, the capping dielectric 130 may have a rectangular profile when the capping dielectric 130 is deposited on the rectangular conductive stack 120, as shown in FIG. 1.

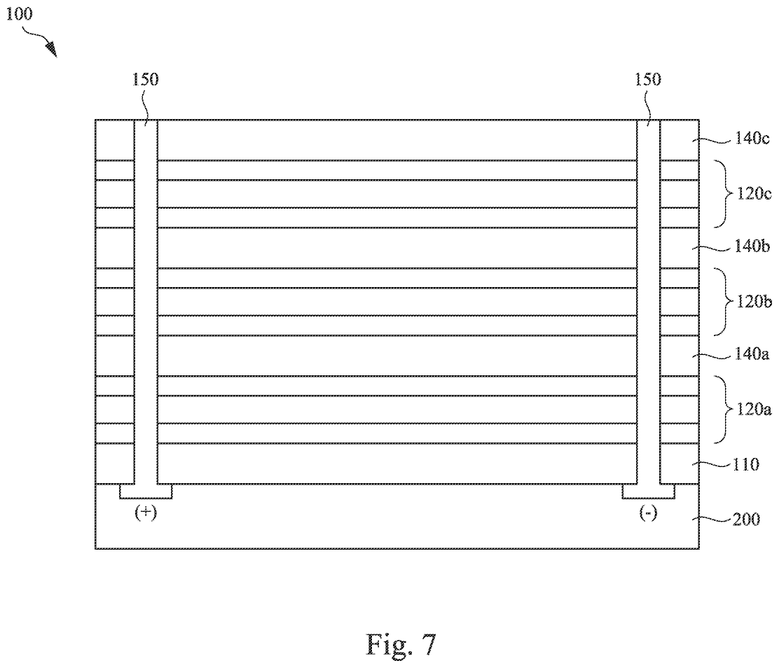

Reference is made to FIG. 7, which is a schematic cross-sectional view of the transparent electrode having optical filtering function, according to some embodiments of the disclosure. In some embodiments, the transparent electrode 100 includes multiple conductive stacks 120, and the transparent electrode 100 is connected to a semiconductor device such as a CMOS image sensor 200. For example, the transparent electrode 100 includes a first conductive stack 120a, a second conductive stack 120b, and a third conductive stack 120c. The transparent electrode 100 further includes a first dielectric layer 140a disposed on the first conductive stack 120a, a second dielectric layer 140b disposed on the second conductive stack 120b, and a third dielectric layer 140c disposed on the third conductive stack 120c. The transparent electrode 100 further includes a plurality of metallic vias 150. The metallic vias 150 penetrating the third dielectric layer 140c, the third conductive stack 120c, the second dielectric layer 140b, the second conductive stack 120b, the first dielectric layer 140a, the first conductive stack 120a, and the substrate 110 to connect to the CMOS image sensor 200. In some embodiments, the material of the metallic vias 150 includes W, or AlCu. In some embodiments, the metallic vias 150 are respectively coupled to positive or negative voltage.

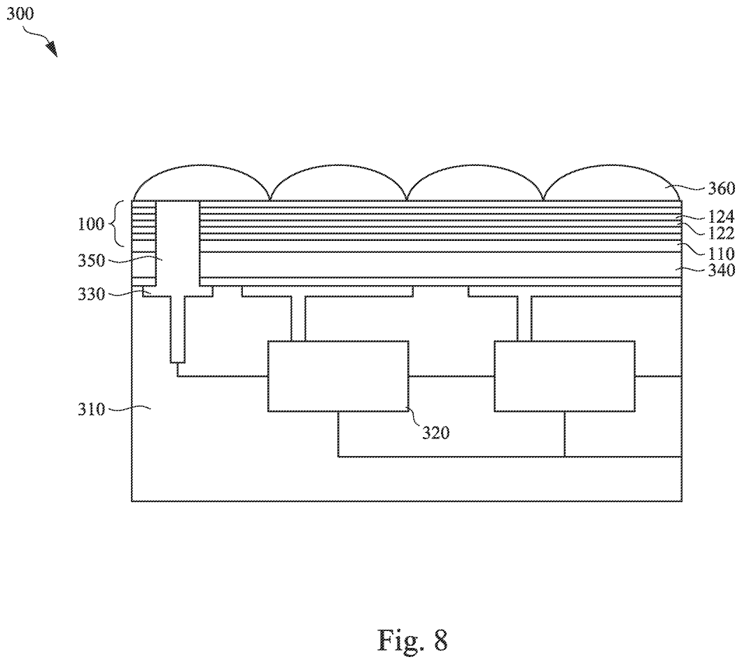

Reference is made to FIG. 8, which is a schematic cross-sectional view of an image sensor, according to some embodiments of the disclosure. The image sensor 300 includes a semiconductor substrate 310, a read-out circuit 320 in the semiconductor substrate 310, a plurality of bottom electrodes 330 disposed on a surface of the semiconductor substrate 310 and coupled to the read-out circuit 320, a photoactive layer 340 disposed on the bottom electrodes 330, the transparent electrode 100 disposed on the photoactive layer 340, and a contact 350 connecting the transparent electrode 100 to the corresponding bottom electrode 330.

In some embodiments, the image sensor 300 is a mono color image sensor. In some embodiments, the photoactive layer 340 includes an organic layer, a quantum dot layer, or a perovskite layer. The photoactive layer 340 continuously extends above the bottom electrodes 330. In some embodiments, the image sensor 300 includes a micro lens layer 360 disposed on the transparent electrode 100.

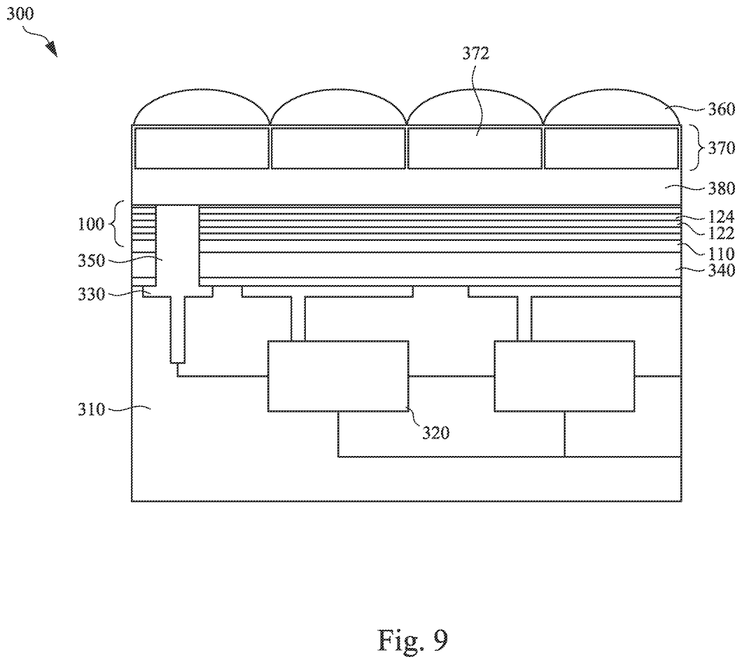

Reference is made to FIG. 9, which is a schematic cross-sectional view of an image sensor, according to some other embodiments of the disclosure. In some embodiments, the image sensor 300 is a color image sensor, and the image sensor 300 further includes a color filter layer 370 disposed between the micro lens layer 360 and the transparent electrode 100. The color filter layer 370 includes a plurality of color filters 372 such as color filters corresponding to red color, green color, blue color, yellow color, clear color, magenta color, and cyan color. The image sensor 300 further includes a spacing layer 380 disposed between the color filter layer 370 and the transparent electrode 100. The spacing layer 380 can be a dielectric material to protect the underlying structure from being damaged during the process of forming the color filter layer 370. In some embodiments, the thickness and the refractive index of the spacing layer 380 can be controlled to adjust the focus of the incident light on the photoactive layer 340.

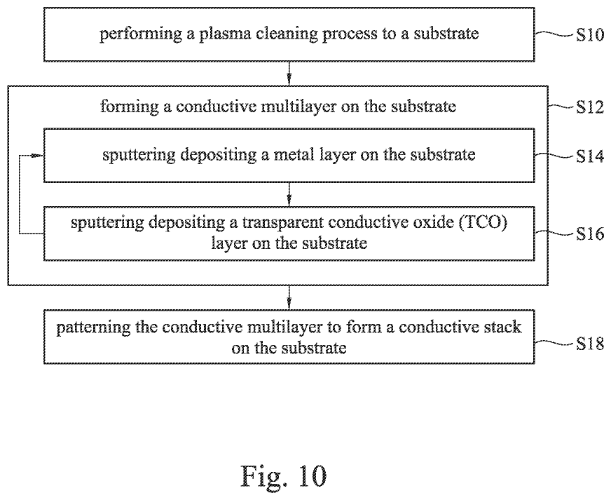

Reference is made to FIG. 10, which is a flow chart of forming a transparent electrode having optical filtering function, according to some embodiments of the disclosure. The method includes step S12 which is forming a conductive multilayer on a substrate. The step S12 includes repeating cycles of step S14 and step S16, in which step S14 is sputtering depositing a metal layer on the substrate, and step S16 is sputtering depositing a transparent conductive oxide (TCO) layer on the substrate.

In some embodiments, the material of the metal layers is selected from a group consisting of Ag, Au, Cu, Fe, Al, Pt, Ni, and combinations thereof. The material of the TCO layers is selected from a group consisting of In₂O₃, In₂O₃—ZnO, AZO, GZO, ITO, IZO, IWO, MZO, ATO, FTO, IGTO, SnO₂, TNO, TIN, Cu₂O, Ta₂Oₓ, GaInOₓ, InGaZnO, ZnₓSnOy, ZnGaₓO_{y}, GaInOₓ, ZnₓIn_{y}O_{z}, VOₓ, and MoOₓ. In some embodiments, the number of the repeating cycles of step S14 and step S16 is from 10 to 30.

After the conductive multilayer is formed on the substrate, the method goes to step S18. In step S18, the conductive multilayer is patterned such that a conductive stack is formed on the substrate, thereby forming the transparent electrode. A sheet resistance of the conductive stack is less than 35 ohms per square, and an average transmittance at a spectral range from 400 nm to 700 nm of the conductive stack is greater than 50%.

In some embodiments, in order to improve adhesion property of the conductive multilayer to the substrate, a step S10 is performed prior to the step S14 and the step S16. In step S10, a plasma cleaning process is performed to the substrate. For example, in step S10, a low power argon plasma cleaning is performed for about 15 minutes inside the sputtering chamber.

In some embodiments, the step S14 of sputtering depositing the metal layer and the step S16 of sputtering depositing the TCO layer are continuously performed such that the metal layers and the TCO layers are continuously deposited on the substrate.

In some embodiments, the sputtering chamber is initially evacuated to a base pressure of about 10⁻⁷-10⁻⁸ Torr. The target to substrate distance is maintained at about 30 cm. In some embodiments, the step S14 of sputtering depositing the metal layer and the step S16 of sputtering depositing the TCO layer are performed at room temperature.

In some embodiments, the step S14 of sputtering depositing the metal layer is performed in pure Ar atmosphere, in which the Ar flow rate is about 30 sccm. The step S16 of sputtering depositing the TCO layer is performed in Ar/O₂ atmosphere, in which the flux ratio is about 18:2.

In some embodiments, a process power used in the step S14 of sputtering depositing the metal layer is higher than a process power used in the step S16 of sputtering depositing the TCO layer. For example, the step S14 of sputtering depositing the metal layer is performed at a constant DC power of 800 W for the Ag target, with a working pressure of 3 mTorr, and the step S16 of sputtering depositing the TCO layer is performed at a constant DC power of 350 W for the IZO target, with a working pressure of 3 mTorr.

In some other embodiments, a working pressure used in the step S14 of sputtering depositing the metal layer is higher than a working pressure used in the step S16 of sputtering depositing the TCO layer, the step S14 of sputtering depositing the metal layer includes using Ag target, and the Ag layer is deposited with DC power of 100 W and working pressure of about 2 mTorr. The step S16 of sputtering depositing the TCO layer includes using TCO target, and the TCO layer is deposited with DC power of 100 W and working pressure of about 1.4 mTorr.

The transparent electrode provided in the present disclosure not only provides IR cut function, but also achieves the requirements for high transparency and good conductivity simultaneously.

It will be apparent to those skilled in the art that various modifications and variations can be made to the structure of the present disclosure without departing from the scope or spirit of the disclosure. In view of the foregoing, it is intended that the present disclosure cover modifications and variations of this invention provided they fall within the scope of the following claims and their equivalents.

What is claimed is:

1. A transparent electrode having optical filtering function, the transparent electrode comprising:
a substrate; and
a conductive stack disposed on the substrate, the conductive stack comprising a plurality of metal layers and a plurality of transparent conductive oxide (TCO) layers alternately arranged, wherein a sheet resistance of the conductive stack is less than 35 ohms per square, and an average transmittance at a spectral range from 400 nm to 700 nm of the conductive stack is greater than 50%.

2. The transparent electrode of claim 1, wherein a thickness of the conductive stack is less than 1.5 μm, and a number of pairs of the metal layers and the TCO layers of the conductive stack is from 10 to 30.

3. The transparent electrode of claim 1, wherein the conductive stack has a rectangle cross-section.

4. The transparent electrode of claim 1, wherein the conductive stack has a trapezoid cross-section, and an angle between a sidewall of the conductive stack and a top surface of the substrate is less than 40 degrees.

5. The transparent electrode of claim 1, wherein an average optical density at a spectral range from 900 nm to 1100 nm of the conductive stack is greater than 2.

6. The transparent electrode of claim 1, wherein a material of the metal layers is selected from a group consisting of Ag, Au, Cu, Fe, Al, Pt, Ni, and combinations thereof.

7. The transparent electrode of claim 1, wherein a material of the TCO layers is selected from a group consisting of In₂O₃, In₂O₃—ZnO, AZO, GZO, ITO, IZO, IWO, MZO, ATO, FTO, IGTO, SnO₂, TNO, TIN, Cu₂O, Ta₂Oₓ, GalnOₓ, InGaZnO, ZnₓSnOy, ZnGaₓO_{y}, GaInOₓ, ZnₓIn_{y}O_{z}, VOₓ, and MoOₓ.

8. The transparent electrode of claim 1, wherein a refractive index of the TCO layers is greater than 1.6, and an extinction coefficient of the TCO layers is less than 0.1, at a spectral range from 400 nm to 700 nm.

9. The transparent electrode of claim 1, further comprising a cap dielectric covering a top surface and sidewalls of the conductive stack, wherein a thickness of the cap dielectric is greater than 200 nm.

10. The transparent electrode of claim 1, further comprising:
a first dielectric layer on the conductive stack;
an additional conductive stack on the first dielectric layer;
a second dielectric layer on the additional conductive stack; and
a metallic via penetrating the conductive stack, the first dielectric layer, the additional conductive stack, and the second dielectric layer.

11. The transparent electrode of claim 1, wherein a S/N ratio of the transparent electrode is greater than 600, at a spectral range from 400 nm to 1000 nm.

12. The transparent electrode of claim 1, wherein a response time of the transparent electrode is greater than 10⁴ Hz, at an applied voltage of 4V.

13. The transparent electrode of claim 1, wherein an ON/OFF ratio of the transparent electrode is greater than 10⁴, at an applied voltage of 0.1V.

14. An image sensor comprising:
a semiconductor substrate;
a read-out circuit in the semiconductor substrate;
a bottom electrode disposed on a surface of the semiconductor substrate;
a photoactive layer disposed on the bottom electrode;
a transparent electrode disposed on the photoactive layer the transparent electrode comprising:
a substrate; and
a conductive stack disposed on the substrate, the conductive stack comprising a plurality of metal layers and a plurality of transparent conductive oxide (TCO) layers alternately arranged, wherein a sheet resistance of the conductive stack is less than 35 ohms per square, and an average transmittance at a spectral range from 400 nm to 700 nm of the conductive stack is greater than 50%; and
a contact connecting the transparent electrode to the bottom electrode.

15. The image sensor of claim 14, wherein the photoactive layer comprises an organic layer, a quantum dot layer, or a perovskite layer.

16. The image sensor of claim 14, further comprising:
a micro lens layer on the transparent electrode;
a color filter layer disposed between the micro lens layer and the transparent electrode; and
a spacing layer disposed between the color filter layer and the transparent electrode.

17. A method of forming a transparent electrode having optical filtering function, the method comprising:
(a) sputtering depositing a metal layer on a substrate;
(b) sputtering depositing a transparent conductive oxide (TCO) layer on the substrate;
repeating step (a) and step (b) such that a conductive multilayer is formed on the substrate; and
patterning the conductive multilayer such that a conductive stack is formed on the substrate, wherein a sheet resistance of the conductive stack is less than 35 ohms per square, and an average transmittance at a spectral range from 400 nm to 700 nm of the conductive stack is greater than 50%.

18. The method of claim 17, wherein the step (a) is performed in Ar atmosphere, and the step (b) is performed in Ar/O₂ atmosphere.

19. The method of claim 17, wherein a process power or a working pressure used in the step (a) is higher than a process power or a working pressure used in the step (b).

20. The method of claim 19, further comprising:
prior to the step (a) and the step (b), performing a plasma cleaning process to the substrate.
